(19) United States
(12) Patent Application Publication
(10) Pub. No.: US 2010/0176476 A1
(43) Pub. Date: Jul. 15, 2010

(54) OPTICAL DEVICE, SOLID-STATE IMAGING DEVICE, AND METHOD

(75) Inventors: Yoshiki TAKAYAMA, Shiga (JP); Tetsumasa MARUO, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/652,229

(22) Filed: Jan. 5, 2010

(30) Foreign Application Priority Data
Jan. 14, 2009 (JP) 2009-005930
Jan. 19, 2009 (JP) 2009-009313
Aug. 6, 2009 (JP) 2009-183899
Dec. 18, 2009 (JP) 2009-288290

(51) Int. Cl. H01L 31/14; G02B 27/00; B26D 3/02; B26D 3/06

(52) U.S. Cl. 257/432; 359/601; 83/39; 83/13; 83/875; 257/E31.097

(57) ABSTRACT

An optical device including: an optical element including a light-receiving unit as a part of a top surface; a transparent member deposited on the optical element to cover the light-receiving unit; and a sealant formed to seal around the transparent member. The transparent member includes: a first protrusion formed in an upper region of a side surface of the transparent member such that a step is created on the side surface; and a tapered surface on an end surface of the first protrusion, the tapered surface being sloped such that a to cross-sectional area of the transparent member decreases towards an upper side of the transparent member. The sealant covers entirely at least a part of the side surface of the transparent member, the part of the side surface being located below the first protrusion.

### BACKGROUND OF THE INVENTION

(1) Field of the Invention

The present invention relates to optical devices, and in particular to an optical device which prevents undesired incident light from entering a light-receiving unit, and a method of manufacturing such an optical device.

(2) Description of the Related Art

In recent years, miniaturization of electronic appliances is increasingly accelerated and optical devices used in electronic appliances are no exception. There is a demand for further miniaturization of optical devices. Thus, conventional optical devices have a structure in which an optical element is stored in a recessed package (container) and the opening is sealed using a protection glass or the like (hereinafter referred to as a “transparent member”). In the field of such conventional optical devices, optical devices are being developed to have a transparent member directly adhered to the optical element, and are thus becoming further miniaturized and thinner.

However, with such a structure having a transparent member directly adhered to the optical element, the distance between the end surface (outer edge surface) of the transparent member and the light-receiving unit is reduced. As a result, undesired incident light is likely to enter the light-receiving unit from the end surface of the transparent member, which causes poor imaging such as flare and a ghost.

In order to prevent such entering of the incident light from outside the end surface of the transparent member, it has been proposed to form a light-shielding layer on the end surface of the transparent member or to make the transparent member larger than the light-receiving unit of the optical element. Further, a technique has also been proposed of preventing the entering of undesired incident light from the end surface by: storing, in a recessed package, a chip having the directly-adhered transparent member; and covering the entire end surface of the transparent member with a light-shielding resin that fills the recessed package (see, for example, Patent Reference 1: Japanese Unexamined Patent Application Publication No. 2007-142194). Furthermore, it has also been proposed that by forming a light-shielding layer not only on the end surface of the transparent member but also on the outer edges of the upper and lower surfaces of the transparent member, or by tilting the end surface of the transparent member, the light entering the inner side of the end surface of the transparent member is prevented from reaching the light-receiving unit by reflection (see, for example, Patent Reference 2: Japanese Unexamined Patent Application Publication No. 2002-261260).

With the structure of conventional optical devices having a light-shielding layer on the end surface of the transparent member, the light-shielding layer needs to be formed on the end surface when the transparent member is by itself. Consequently, it becomes necessary to provide a facility and a process for forming the light-shielding layer, and thus the yield deteriorates. As a result, the cost of the transparent member increases.

Moreover, with the conventional optical devices having a transparent member enlarged with respect to the light-receiving unit of the optical element, the package size must obviously be enlarged. As a consequence, the miniaturization of the optical devices becomes difficult, and the cost increases.

Furthermore, with the conventional optical devices in which a light-shielding resin is applied to the end surface of the transparent member, it is necessary to cover the entire end surface of the transparent member with the light-shielding resin. Since there is always an error in the region of the light-shielding resin covering the end surface of the transparent member, a situation occurs where the light-shielding resin overtops the upper surface of the transparent member or the light-shielding resin cannot cover the upper portion of the end surface of the transparent member. As a result, favorable imaging characteristics cannot be obtained.

A significant characteristic of the structure having the transparent member directly adhered to the chip is that the upper surface of the transparent member having a small slope with respect to the upper surface of the optical element can be used as an optical reference surface at the time of mounting optical components. Therefore, it has been a challenge to prevent the entering of undesired incident light from the end surface of the transparent member without the light-shielding resin overtopping the upper surface of the transparent member.

### SUMMARY OF THE INVENTION

In view of the above, an object of the present invention is to prevent, in an optical device having a transparent member covering an optical element, undesired incident light or reflected light from the end surface of the transparent member from entering a light-receiving unit, and to achieve miniaturization and cost reduction.

The optical device according to an aspect of the present invention is an optical device including: an optical element including a light-receiving unit; a transparent member deposited on the optical element to cover the light-receiving unit; and a sealant formed to seal around the transparent member. The transparent member includes: a first protrusion formed in an upper region of a side surface of the transparent member such that a step is created on the side surface; and a tapered surface on an end surface of the first protrusion, the tapered surface being sloped such that a cross-sectional area of the transparent member decreases towards an upper side of the transparent member. The sealant covers entirely at least a part of the side surface of the transparent member, the part of the side surface being located below the first protrusion.

With the above structure, incident light entering from the tapered surface of the transparent member is less likely to reach the light-receiving unit according to the Snell's law. Further, by covering the side surface below the step with the sealant, it is possible to prevent entering of undesired incident light from the side surface of the first protrusion (the tapered surface and the perpendicular surface). As a result, the optical characteristics of the optical device improve, and further miniaturization becomes possible.

Further, the tapered surface may have a horizontal length longer than its vertical length. In other words, an angle between an upper surface of the transparent member and the tapered surface (taper angle) may be equal to or smaller than 45°. According to the Snell's law, the longer the horizontal length of the tapered surface in comparison with the vertical length, that is, the smaller the taper angle, the less it is likely for the incident light entering from the tapered surface to reach the light-receiving unit of the optical element.

Furthermore, the tapered surface may be rougher than a different surface of the transparent member on which the tapered surface is not provided. The rougher the tapered surface of the transparent member, the greater the attenuation is of the incident light entering from the tapered surface. In addition, in the case of filling with a later-described sealant, the upper surface position of the sealant can be easily controlled, thereby making it possible to effectively prevent the sealant from overtopping the upper surface of the transparent member.

In addition, a ridge line of the transparent member except for the tapered surface may be chamfered. The “ridge line” indicates a boundary between adjacent surfaces. Also, “chamfering” includes tapering (chamfering), R-shaping (round chamfering), and so on. Moreover, in the optical device according to an aspect of the present invention, the transparent member may further include a second protrusion in a lower region of the side surface, the second protrusion being formed to create, together with the first protrusion, a recess at the step.

Here, when assuming that: the distance between the upper surface and the lower surface of the first protrusion is Y; the length of the lower surface of the first protrusion in the protruding direction is X; the maximum angle of outer incident light in the air, for example, is θ1; the maximum angle of outer incident light in the transparent member is θ2; the refractive index in the air is n1; and the refractive index of the transparent member is n2, it is possible to calculate X and Y using relational expressions of θ2=ASIN ((n1·sin θ1)/n2) and X=TAN θ2·Y.

Further, the sealant may be made of a light-shielding material. This allows partial shielding of the incident light entering the end surface (including the tapered surface) of the transparent member.

Furthermore, it is sufficient to set the above Y of the first protrusion so that a height of the sealant covering the side surface of the transparent member reaches a point between a lower surface and an upper surface of the first protrusion, taking into consideration the possibility of error in the sealant height. This allows calculation of a minimum necessary length for the above X of the first protrusion using the above relational expressions.

In addition, the optical device further includes a case for storing the optical element and the transparent member. The sealant fills an inside of the case and seals a space defined by surfaces of the optical element, the transparent member, and the case. The upper surface of the sealant may be higher than a lower end of the tapered surface but lower than an upper end of the tapered surface. This allows effective prevention of the sealant from overtopping the upper surface of the transparent member.

The solid-state imaging device according to an aspect of the present invention is a solid-state imaging device including: a solid-state imaging element including a light-receiving unit; a transparent member deposited on the solid-state imaging element to cover the light-receiving unit; and a sealant formed to seal around the transparent member. The transparent member includes: a first protrusion formed in an upper region of a side surface of the transparent member such that a step is created on the side surface; and a tapered surface on an end surface of the first protrusion, the tapered surface being sloped such that a cross-sectional area of the transparent member decreases towards an upper side of the transparent member. The sealant covers entirely at least a part of the side surface of the transparent member, the part of the side surface being located below the first protrusion.

The method according to an aspect of the present invention is a method for forming the first protrusion and the tapered surface on the above-described transparent member. More specifically, the method includes: forming a recess to create the step on a lower surface of a substrate which is an original material of the transparent member; forming a V-shaped groove on an upper surface of the substrate directly above the recess, using a V-shaped cutting tool having an angle of contact equal to an angle between the upper surface of the transparent member and the tapered surface; and cutting the substrate using a deepest part of the V-shaped groove as a base point.

Further, the forming a V-shaped groove and the cutting the substrate may be performed simultaneously, using a combined cutting tool that includes: a V-shaped first cutting tool having an angle of contact equal to the angle between the upper surface of the transparent member and the tapered surface; and a second cutting tool which is mounted to a tip of the first cutting tool and cuts the substrate in a direction perpendicular to the upper surface of the substrate, the substrate being the original material of the transparent member.

According to the present invention, the provision of: the protrusion on the side surface of the transparent member; and the tapered surface on the end surface of the protrusion has made it possible to effectively prevent undesired incident light, which enters from the end surface of the transparent member and has an adverse effect on the optical characteristics, from reaching the light-receiving unit.

### FURTHER INFORMATION ABOUT TECHNICAL BACKGROUND TO THIS APPLICATION

The disclosures of Japanese Patent Applications No. 2009-005930 filed on Jan. 14, 2009, No. 2009-009313 filed on Jan. 19, 2009, No. 2009-183899 filed on Aug. 6, 2009, and No. 2009-288290 filed on Dec. 18, 2009 including specification, drawings and claims are incorporated herein by reference in their entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a plan view of an optical device according to Embodiment 1;

FIG. 1B is a sectional view taken along the IB-IB line of FIG. 1A;

FIG. 1C is an enlarged view of the section A of FIG. 1B;

FIG. 1D shows an example of a method for manufacturing an optical device according to Embodiment 1;

FIG. 2A is a plan view of an optical device according to Embodiment 2;

FIG. 2B is a sectional view taken along the IIB-IIB line of FIG. 2A;

FIG. 3A shows a traveling distance of undesired incident light in a conventional optical device;

FIG. 3B shows a traveling distance of undesired incident light in an optical device according to Embodiment 2;

FIG. 4 shows an example of a method for cutting out a transparent member;

FIG. 5 shows another example of a method for cutting out a transparent member;

FIG. 6A is a plan view of an optical device according to Embodiment 3;

FIG. 6B is a sectional view taken along the VIB-VIB line of FIG. 6A;

FIG. 7A is a plan view of an optical device according to Embodiment 4;

FIG. 7B is a sectional view taken along the VIIB-VIIB line of FIG. 7A;

FIG. 8A shows an example of a method for manufacturing an optical device according to Embodiment 4, and shows a state before forming a recess;

FIG. 8B shows an example of a method for manufacturing an optical device according to Embodiment 4, and shows a state of forming a recess;

FIG. 8C shows an example of a method for manufacturing an optical device according to Embodiment 4, and shows a state after forming a recess;

FIG. 8D shows an example of a method for manufacturing an optical device according to Embodiment 4, and shows a state before cutting a base material;

FIG. 8E shows an example of a method for manufacturing an optical device according to Embodiment 4, and shows a state of cutting a base material;

FIG. 8F shows an example of a method for manufacturing an optical device according to Embodiment 4, and shows a state after cutting a base material;

FIG. 9A shows an example of a method for manufacturing an optical device according to Embodiment 4, and shows a state before forming a protrusion and cutting a base material;

FIG. 9B shows an example of a method for manufacturing an optical device according to Embodiment 4, and shows a state of simultaneously forming a protrusion and cutting a base material;

FIG. 9C shows an example of a method for manufacturing an optical device according to Embodiment 4, and shows a state after forming a protrusion and cutting a base material;

FIG. 10 is a sectional view of an optical device according to Embodiment 5;

FIG. 11A is a plan view of an optical device according to Embodiment 6; and

FIG. 11B is a sectional view taken along the XIB-XIB line of FIG. 11A.

### DESCRIPTION OF THE PREFERRED EMBODIMENT(S)

Hereinafter, embodiments of the present invention are described with reference to the drawings.

### Embodiment 1

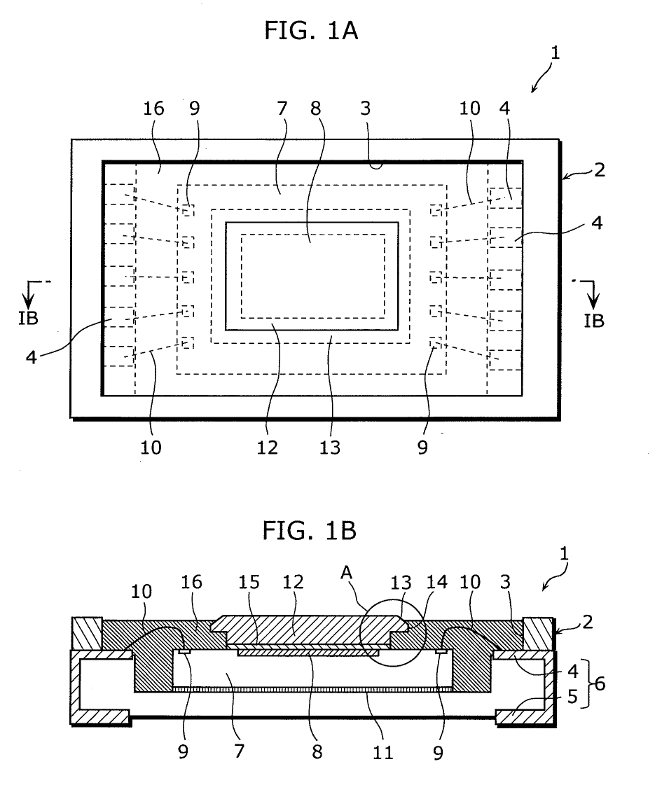

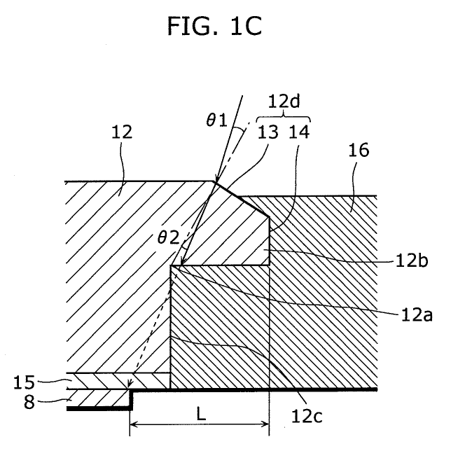

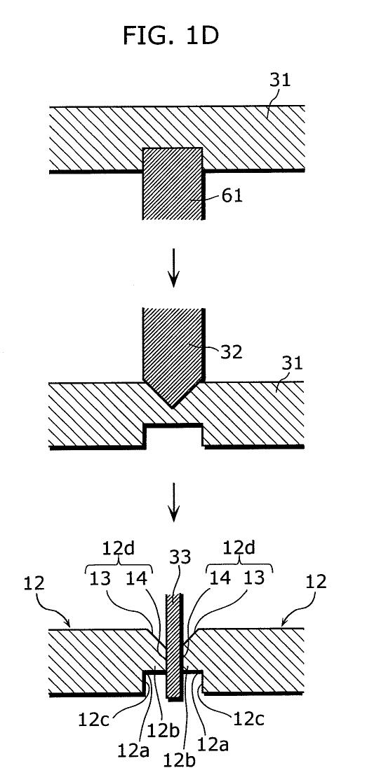

FIG. 1A is a plan view of an optical device of Embodiment 1 of the present invention. FIG. 1B is a sectional view taken along the IB-IB line of the optical device shown in FIG. 1A. FIG. 1C is an enlarged view of the section A of FIG. 1B. FIG. 1D shows a method for manufacturing a transparent member which is a constituent element of the optical device. As shown in FIGS. 1A to 1D, an optical device 1 primarily includes a case (optical element support) 2, an optical element 7, a transparent member 12, and a sealant 16. The optical device 1 is typically a solid-state imaging device.

The case 2 includes a recess 3 which stores the optical element 7 and the transparent member 12, and leads 6 extending from the inside to the outside of the recess 3. Each lead 6 includes an internal electrode 4 exposed inside the recess 3 and an external electrode 5 exposed outside the case 2.

The optical element 7 includes a light-receiving unit 8 formed at the center of the upper surface and plural electrodes 9 formed at the outer edges of the upper surface. The electrodes 9 are electrically connected to the light-receiving unit 8, and each of the electrodes 9 is also electrically connected to a corresponding internal electrode 4 of the case 2 via a corresponding one of wires 10. The optical element 7 is adhered to the bottom of the recess 3 of the case 2 using a die bonding (DB) material 11. The optical element 7 is an imaging sensor (solid-state imaging element), for example. That is to say, the light-receiving unit 8 includes plural photodiodes which respectively correspond to pixels and are arranged in a matrix.

The transparent member 12 is an approximately rectangular flat plate member which is smaller than the optical element 7 but larger than the light-receiving unit 8. The transparent member 12 is deposited on the upper surface of the optical element 7 to cover the light-receiving unit 8. The material of the transparent member 12 may be glass, an infrared (IR) cut filter, or an optical low-pass filter, for example, but is generally glass. The upper surface of the transparent member 12 is exposed, and the lower surface of the transparent member 12 is adhered to the upper surface of the optical element 7 using a resin adhesive 15. As the resin adhesive 15, a transparent resin material such as an acrylic resin, an epoxy resin, or a silicon resin is used.

As shown in FIG. 1C, the transparent member 12 includes a protrusion 12b to form a step 12a on the side surface. The transparent member 12 includes, as its side surface, an end surface 12c located below the step 12a and an end surface 12d of the protrusion 12b which is above the step 12a.

The protrusion 12b is typically a projection extending all around the side surface of the transparent member 12. However, the protrusion 12b is not limited to this, and may be plural projections formed with a space between one another. Alternatively, in the case of using the optical device for restricting the incident light direction to a specific direction, the protrusion 12b may be selectively formed only along the specific direction.

Further, the end surface of the protrusion 12b includes a tapered surface 13 which continues into the upper surface side and a perpendicular surface 14 which continues into the lower surface side. The tapered surface 13 is a surface sloped such that the cross-sectional area of the protrusion 12b (the area of the cross section parallel to the upper surface) gradually decreases towards the upper side of the transparent member 12. The perpendicular surface 14 is a surface approximately perpendicular to the lower surface of the protrusion 12b.

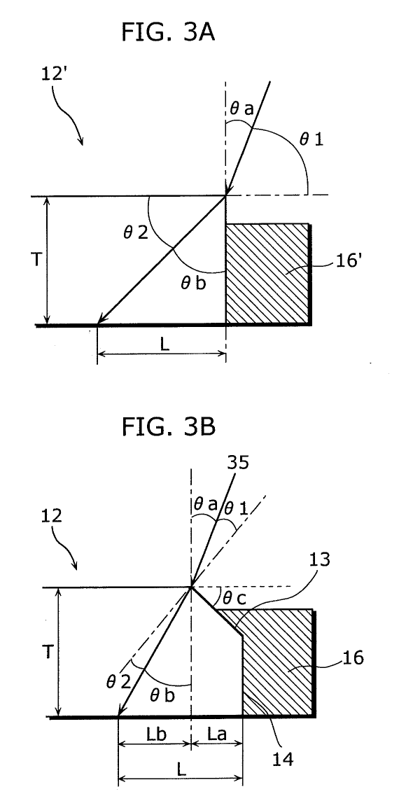

As shown in FIGS. 3A and 3B, a refraction angle 82 of incident light significantly differs depending on whether the entire end surface of the protrusion 12b is the perpendicular surface (FIG. 3A) or the upper region of the end surface of the protrusion 12b is the tapered surface 13 (FIG. 3B). More specifically, providing the tapered surface allows the traveling direction of light passing through the transparent member 12 to approach the vertical line. The details are described later.

As shown in FIG. 1C, the end surface 12c below the step 12a is provided at a position horizontally recessed with respect to the upper end of the tapered surface 13. To put it differently, the cross-sectional area of the transparent member 12 at the upper end of the tapered surface 13 is larger than the cross-sectional area of the transparent member 12 below the step 12a.

Such a positional relationship allows incident light entering the upper end of the tapered surface 13 (arrow in FIG. 1C) to pass through the lower surface of the protrusion 12b. As a result, the incident light entering the tapered surface 13 can be effectively prevented from reaching the light-receiving unit 8.

The sealant 16 fills the inside of the case 2 to seal the space defined by the surfaces of the optical element 7, the transparent member 12, and the case 2. The sealant 16 may be made of a transparent resin material such as an acrylic resin, an epoxy resin, or a silicon resin. The sealant 16 may also be made of a light-shielding material

As shown in FIG. 1C, the sealant 16 is formed such that at least the end surface 12c is all covered, that is, the height of the upper surface of the sealant 16 reaches a point higher than the upper end of the end surface 12c but lower than the upper end of the end surface 12d. The sealant 16 according to Embodiment 1 covers a part of the tapered surface 13 of the transparent member 12 and the entire region of the perpendicular surface 14 of the transparent member 12 to prevent entering of light from the end surface of the transparent member 12.

Next, with reference to FIG. 1D, a method for manufacturing the transparent member 12 having the above structure is described. It is to be noted that the processes below are the same as those shown in FIGS. 4, 5, 8A to 8F, and 9A to 9C, and thus the details thereof are described later.

Initially, as shown at the top of FIG. 1D, a recess is created on the lower surface of a substrate 31, which is the original material of the transparent member 12, using a half-cutting blade 61. The recess is the part to become the steps 12a later. That is to say, the side walls of the recess are equivalent to the end surfaces 12c.

Next, as shown in the middle of FIG. 1D, a V-shaped groove is formed at a position on the upper surface of the substrate 31 directly above the recess using a half-cutting blade 32. The V-shaped groove is the part to become the tapered surfaces 13 later.

Next, as shown at the bottom of FIG. 1D, the substrate 31 is cut using a full-cutting blade 33, with the deepest part of the V-shaped groove serving as a base point. This makes it possible to obtain the transparent members 12 each having the step 12a, the protrusion 12b, the end surfaces 12c and 12d, the tapered surface 13, the perpendicular surface 14, and so on.

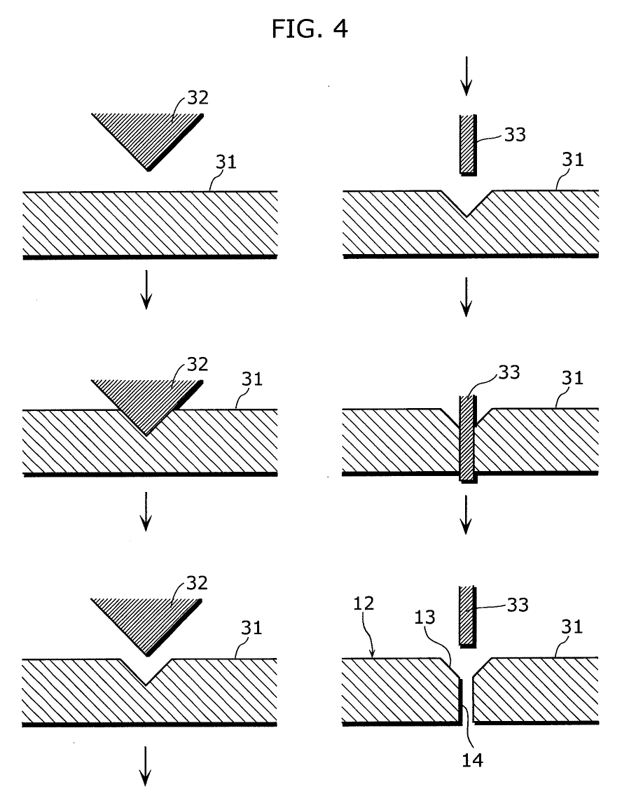

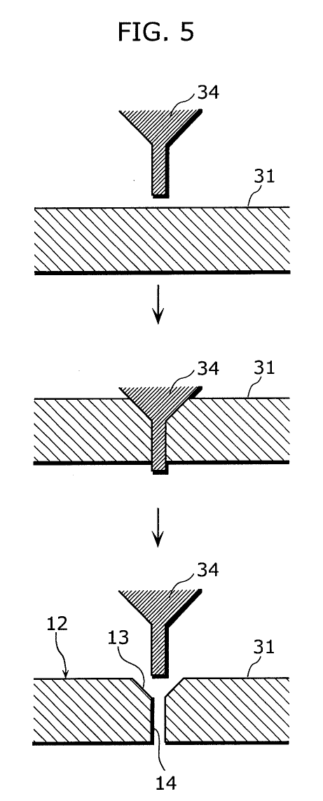

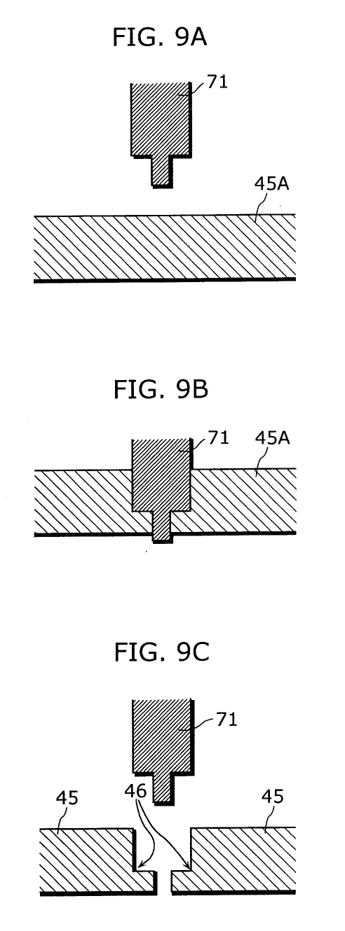

The method for manufacturing the transparent member 12 is not limited to the example shown in FIG. 1D. For example, the recess may be formed on the lower surface after the V-shaped groove is formed on the upper surface, or the V-shaped groove and the recess may be formed simultaneously. Also, after forming the recess, the substrate 31 may be cut simultaneously with the forming of the V-shaped groove, using an integrally-structured blade 34 shown in FIG. 5. Similarly, after forming the V-shaped groove, the substrate 31 may be cut simultaneously with the forming of the recess, using an integrally-structured blade 71 shown in FIG. 9A.

Described hereinafter is an advantageous effect produced as a result of providing the tapered surface 13 to the transparent member 12, as well as an advantageous effect produced as a result of providing the step 12a to the transparent member 12. Embodiments 2 and 3 describe an advantageous effect produced by the tapered surface 13, whereas Embodiments 4 to 6 describe an advantageous effect produced by the step 12a.

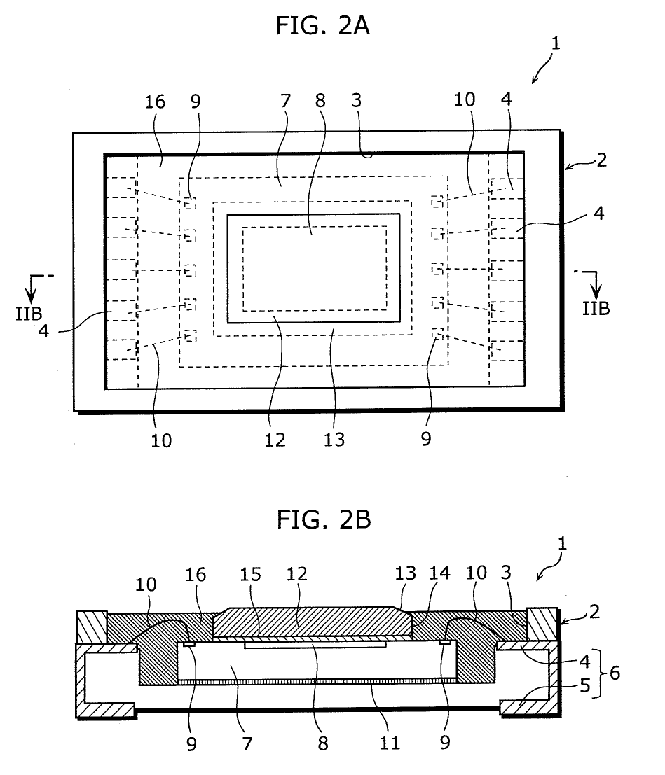

First, described in detail with reference to FIGS. 2A to 6B is an advantageous effect produced as a result of providing the tapered surface to the transparent member.

### Embodiment 2

FIG. 2A is a plan view of an optical device of Embodiment 2 of the present invention. FIG. 2B is a sectional view taken along the IIB-IIB line of the optical device shown in FIG. 2A. As shown in FIGS. 2A to 2B, the optical device 1 primarily includes the case (optical element support) 2, the optical element 7, the transparent member 12, and the sealant 16. The optical device 1 is typically a solid-state imaging device. It is to be noted that the structure of the optical device 1 shown in FIGS. 2A and 2B is the same as that shown in FIGS. 1A and 1B except that the step 12a is not provided in the transparent member 12. Thus, the same reference numerals are used and detailed descriptions are omitted.

Next, FIG. 3A shows a traveling distance of incident light 35 entering the upper end of the end surface of a conventional transparent member 12′ (a position illimitably close to the upper surface of the transparent member 12′). FIG. 3B shows a traveling distance of the incident light 35 entering the upper end of the tapered surface 13 of the transparent member 12 of the present invention (a position illimitably close to the upper surface of the transparent member 12).

As shown in FIGS. 3A and 3B, in the case where the respective upper surfaces of the sealants 16 and 16′ are located lower than the respective upper surfaces of the transparent members 12 and 12′, the incident light 35 enters from the parts of the transparent members 12 and 12′ that are not covered by the sealants 16 and 16′ (the tapered surface 13 in the case of FIG. 3B). Therefore, it is necessary to prevent the light entering the end surfaces (the tapered surface 13 in the case of FIG. 3B) from reaching the light-receiving unit 8, by making the size of the transparent members 12 and 12′ larger than the light-receiving unit 8.

In FIGS. 3A and 3B, θ1 indicates an incident angle of the incident light 35; θ2 indicates a refraction angle of the incident light 35; θa indicates an angle between the incident light 35 and the respective end surfaces of the transparent members 12 and 12′ (the perpendicular surface 14 in the case of FIG. 3B); θb indicates an angle between refracted light and the respective end surfaces of the transparent members 12 and 12′ (the perpendicular surface 14 in the case of FIG. 3B); θc indicates an angle between the upper surface of the transparent member 12 and the tapered surface 13 (hereinafter referred to as a “taper angle”); La indicates the horizontal length of the tapered surface 13 (hereinafter referred to as a “taper length”); T indicates the height of the transparent members 12 and 12′; n2 indicates the refractive index of the transparent members 12 and 12′; and L indicates a horizontal traveling distance between the respective end surfaces of the transparent members 12 and 12′ and the point to which the incident light 35 has traveled.

In the case of assuming, as current typical values, θa=20°, θc (taper angle)=45°, La (taper length)=0.2 mm, T (height of the transparent members)=0.5 mm, n2 (refractive index of the transparent members)=1.5, it is possible to calculate the traveling distance L of the incident light 35 entering the upper ends of the end surfaces of the transparent members 12 and 12′ (the upper end of the tapered surface 13 in the case of FIG. 3B) according to the Snell's law (Eq. 1).

$$\begin{matrix}[ Math 1 ] & \\ \frac{sin ϑ 1}{sin ϑ 2} = n 2 & ( Eq . 1 )\end{matrix}$$

Initially, in the case of the conventional transparent member 12′ shown in FIG. 3A (the transparent member which does not have the tapered surface), the following applies: θ1=90−θa=70°; θ2=arcsin (sin (θ1)/n2)=38.8°; θb=90−θ2=51.2°; and L=TAN θb*T=0.62 mm.

On the other hand, in the case of the transparent member 12 of the present invention shown in FIG. 3B (the transparent member having the tapered surface 13), the following applies: θ1=θc−θa=25°; θ2=arcsin (sin (θ1)/n2)=16.4°; θb=θc−θ2=28.6°; Lb=Tan θb*T=0.27 mm; and L=La+Lb=0.47 mm.

Thus, it can be appreciated that the transparent member 12 of the present invention shown in FIG. 3B makes it more difficult for the incident light 35 to reach the light-receiving unit 8. As a result, the transparent member 12 according to the present invention can be miniaturized as compared to the conventional transparent member 12′.

In the present invention, the height of the sealant 16 covering the end surface of the transparent member 12 (the position of the upper surface of the sealant 16) is sufficient as long as the height reaches a point between the lower end and the upper end of the tapered surface 13, that is, a position higher than the lower end of the tapered surface 13 but lower than the upper end of the tapered surface 13. The dimensions of the tapered surface 13 can be determined within a range in which unevenness of the sealant 16 can be accommodated. That is to say, when the unevenness of the sealant 16 is small, the dimensions of the tapered surface 13 can be designed small, which makes it possible to keep short the traveling distance L of the undesired incident light 35 which enters from the tapered surface 13 of the transparent member 12.

In addition, the dimensions of the tapered surface 13 of the transparent member 12 are such that the length of the tapered surface 13 on the upper surface side (the horizontal length of the tapered surface 13) is longer than the length of the tapered surface 13 on the end surface side (the vertical length of the tapered surface 13). The greater the ratio of the horizontal length to the vertical length, the shorter the traveling distance L of the undesired incident light 35 it is possible to keep.

Here, the relationship between the refraction angle θb and the tapered angle θc is considered using a specific example. First, the following are assumed: the refractive index n1 in the air is 1; the refractive index n2 of the transparent member is 1.5; and the incident angle θa is 20°. Assigning the tapered angle θc 45° to the above expressions gives θ1≈25°, θ2≈16°, and θb≈29°. Assigning the tapered angle θc 30° to the above expressions gives θ1≈10°, θ2≈7°, and θb≈23°. Assigning the tapered angle θc 15° to the above expressions gives θ1≈5°, θ2≈3°, and θb≈18°.

This shows that the refraction angle θb becomes smaller when the tapered angle θc is smaller. As apparent from FIG. 3B, the traveling distance L (more specifically, Lb) becomes shorter when the refraction angle θb is smaller. That means, to obtain a shorter traveling distance L, it is sufficient to reduce the tapered angle θc. The traveling distance L of the undesired incident light 35 can be kept short when the tapered angle θc is set to preferably 45° or smaller, more preferably 30° or smaller, and further preferably 15° or smaller.

It is to be noted that although Embodiment 2 has shown the example of the transparent member 12 having the tapered surface 13 and the perpendicular surface 14 on the end surface, the transparent member 12 is not limited to this. The entire end surface of the transparent member 12 may be the tapered surface 13. In other words, the transparent member 12 may be an isosceles trapezoid having the upper surface as the shorter side, the lower surface as the longer side, and the end surfaces as the oblique sides.

Further, the undesired incident light 35 can be attenuated by making the tapered surface 13 of the transparent member 12 rougher than the upper surface of the transparent member 12. The rougher the tapered surface 13, the greater the attenuation is and thus the greater the effect is of preventing the entering of the undesired incident light 35.

In addition, by making the tapered surface 13 of the transparent member 12 rougher than the other surfaces of the transparent member 12, that is, the surfaces except for the tapered surface 13 (particularly the upper surface and the perpendicular surface 14), it becomes more difficult for the sealant 16 to rise along the tapered surface 13 of the transparent member 12. As a result, the position of the upper surface of the sealant 16 can be more easily controlled, thereby making it effective in preventing the sealant 16 from overtopping the upper surface of the transparent member 12.

As described above, even through the roughening of the tapered surface 13, it is possible to prevent the entering of the undesired incident light 35 which cannot be estimated by optical designing, thereby making it possible to obtain high optical characteristics.

Further, although the transparent member 12 in Embodiment 2 shown in FIGS. 2A and 2B does not have a taper or the like on the ridge line (boundary between adjacent surfaces) aside from the tapered surface 13, it is needless to say that a taper, a round shape, or the like may be formed at a necessary position if needed (not shown).

Next, a cutting method for forming the tapered surface 13 of the transparent member 12 is described with reference to FIGS. 4 and 5.

FIG. 4 shows an example of a method for cutting out the transparent member 12. The transparent member 12 is manufactured by dividing the substrate 31, which is the original material of the transparent member 12, into the dimensions of each transparent member. The cutting tools used in the embodiment shown in FIG. 4 are a V-shaped half-cutting blade 32 having an angle of contact equal to the taper angle of the tapered surface 13 (a first cutting tool) and a full-cutting blade 33 which cuts the substrate 31 in the direction perpendicular to the upper surface of the substrate 31 (a second cutting tool). The “angle of contact” indicates the angle between the half-cutting blade 32 and the surface (upper surface) of the substrate 31.

Initially, sloped surfaces, which are to become the tapered surfaces 13, are formed on the substrate 31. More specifically, with the half-cutting blade 32 that can be used for half-cutting in V-shape, a V-shaped groove is formed so that the dimension of the transparent member 12 between the upper end of the end surface of the transparent member 12 and the lower end of the tapered surface 13 is created (half-cutting process). After that, using the full-cutting blade 33 which cuts into the dimensions of each transparent member, the substrate 31 is cut with the deepest part of the V-shaped groove serving as a base point (full-cutting process).

This allows forming of the tapered surfaces 13 on the end surfaces of the transparent member 12. However, since the full-cutting blade 33 has a predetermined thickness, the V-shaped groove needs to be made a little larger than the tapered surfaces 13 in the half-cutting process. By performing the above processes for each side of the transparent members 12, it is possible to cut out the transparent members 12 from the substrate 31.

It is to be noted that after the above processes, the tapered surface 13 can be made rougher than the upper surface of the transparent member 12 if grinding of the tapered surface 13 is omitted. Further, the tapered surface 13 can be made rougher than the perpendicular surface 14 by making the half-cutting blade 32 rougher than the full-cutting blade 33.

FIG. 5 shows another example of a method for cutting out the transparent member 12. The cutting tool used in the embodiment shown in FIG. 5 is an integrally-structured blade 34 having the full-cutting blade 33 mounted to the tip of the half-cutting blade 32 shown in FIG. 4 (combined cutting tool). This makes it possible to simultaneously cut the substrate 31 and form the tapered surface 13 in the boundary region between the upper surface and the end surface of the substrate 31.

### Embodiment 3

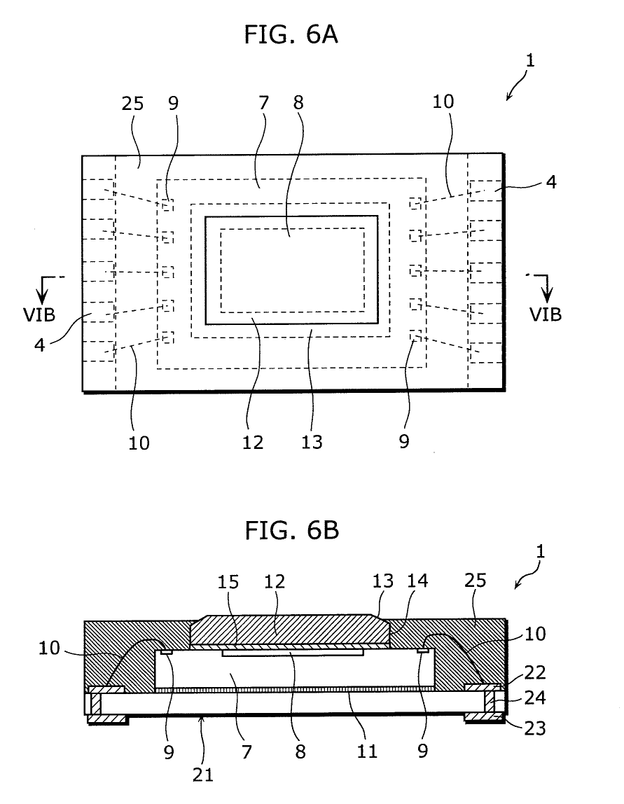

FIG. 6A is a plan view of the optical device 1 of Embodiment 3 in the present invention. FIG. 6B is a sectional view taken along the VIB-VIB line of the optical device 1 shown in FIG. 6A. The present embodiment is different from Embodiment 2 in that the optical element 7 and the transparent member 12 are packaged using a circuit substrate 21.

The circuit substrate 21 has a circuit thereon, and is formed with a resin or ceramics as the base material. Internal electrodes 22 are formed on one side of the circuit substrate 21, and external electrodes 23 are formed on the other side of the circuit substrate 21. The circuit substrate 21 is also formed with vias 24 which allow electrical conduction of the internal electrodes 22 and the external electrodes 23 (the vias may be inner-layer wires or the like). The lower surface of the optical element 7 is adhered to a predetermined position of the circuit substrate 21, and each electrode 9 on the upper surface of the optical element 7 is electrically connected to a corresponding internal electrode 22 of the circuit substrate 21 via a corresponding wire 10. A sealant 25, which also has a function to shield light entering the end surface of the transparent member 12, is used for sealing in such a manner that the transparent member 12 has an opening thereon. Further, it is needless to say that the shape of the end surface of the transparent member 12 and the height of the sealant 25 covering the end surface of the transparent member 12 are the same as in Embodiment 2.

This structure does not include a side wall such as the above-described case 2, thereby allowing further miniaturization. A lead frame may be used in place of the circuit substrate 21 for packaging in the same manner. The use of the circuit substrate 21 or the lead frame allows various and general-purpose packaging, thereby making cost reduction possible.

The expressions such as “upper surface”, “lower surface”, “horizontal”, and “vertical” in this Specification are used presuming that the optical device 1 shown in FIGS. 2A and 2B is placed on a horizontal plane. Thus, the above expressions should be interpreted in a relative sense, rather than an absolute sense. The same holds true for the other embodiments.

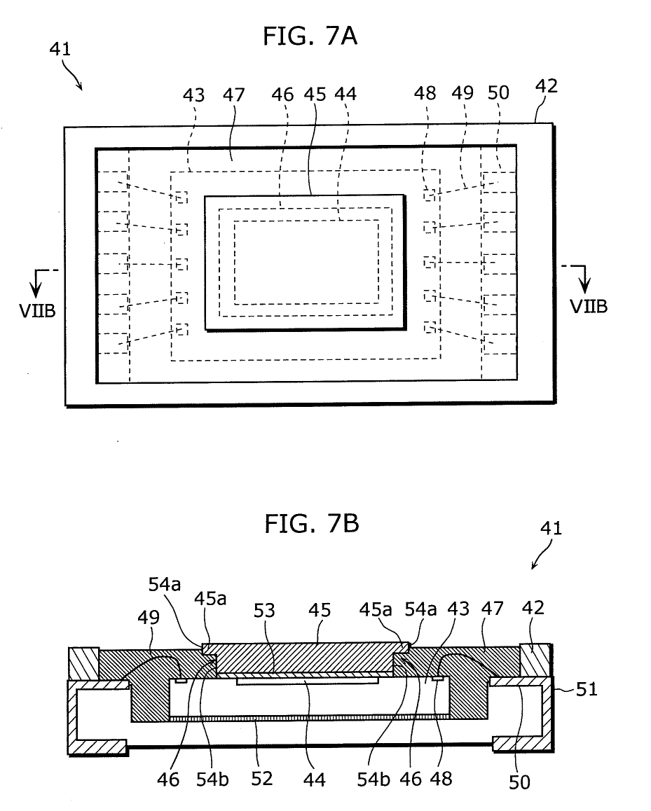

Described next in detail with reference to FIGS. 7A to 11B is an advantageous effect produced as a result of providing the step to the transparent member.

### Embodiment 4

### <Structure of Optical Device>

FIG. 7A is a plan view showing the structure of an optical device 41 according to Embodiment 4. FIG. 7B is a cross-sectional view taken along the VIIB-VIIB line of FIG. 7A.

As shown in FIGS. 7A and 7B, in a recess of a housing 42 (equivalent to the “case 2” of Embodiment 1) which is made of an epoxy resin or alumina ceramics, for example, and serves as a semiconductor package, an optical element 43 (equivalent to the “optical element 7” of Embodiment 1) having a light-receiving unit 44 (equivalent to the “light-receiving unit 8” of Embodiment 1) at the center of the surface of the optical element 43 is provided via a die bonding material 52 (equivalent to the “DB material” of Embodiment 1).

On the optical element 43, a transparent member 45 (equivalent to the “transparent member 12” of Embodiment 1), which is an approximately rectangular flat plate member, is formed via a resin adhesive 53 (equivalent to the “resin adhesive 15” of Embodiment 1) such that the light-receiving unit 44 is covered. The resin adhesive 53 is made of a transparent resin material such as an acrylic resin, an epoxy resin, or a silicon resin.

Electrodes 48 (equivalent to the “electrodes 9” of Embodiment 1) are formed at the surface edges of the optical element 43 and are electrically connected to the light-receiving unit 44. For example, each electrode 48 is connected, via a corresponding one of thin metal wires 49 made of Al or Au (equivalent to the “wires 10” of Embodiment 1), to a corresponding one of internal electrodes 50 (equivalent to the “internal electrodes 4” of Embodiment 1) of leads 51 (equivalent to the “leads 6” of Embodiment 1) each of which has connection terminals internally and externally. In the recess of the housing 42, the region where the optical element 43 and the transparent member 45 are not provided is filled with a sealing resin 47 which shields light (equivalent to the “sealant 16” of Embodiment 1). It is to be noted that the optical element 43 is an imaging sensor and the like having the light-receiving unit 44 as an imaging area.

Here, the transparent member 45 has a protrusion 45a (equivalent to the “protrusion 12b” of Embodiment 1) so that a step 46 (equivalent to the “step 12a” of Embodiment 1) is formed on the side surface of the transparent member 45. The transparent member 45 has, as its side surface, an end surface 54b below the step 46 (equivalent to the “end surface 12c” of Embodiment 1) and an end surface 54a of the protrusion 45a above the step 46 (equivalent to the “end surface 12d” of Embodiment 1).

The sealing resin 47 is formed such that at least the end surface 54b is all covered, that is, the height of the sealing resin 47 reaches a point higher than the upper end of the end surface 54b but lower than the upper end of the end surface 54a. The material of the transparent member 45 may be glass, an IR cut filter, or an optical low-pass filter, for example, but is generally glass.

The distance between the upper surface and the lower surface of the protrusion 45a, that is, the distance between the upper end and the lower end of the end surface 54a of the protrusion 45a, and the length of the lower surface of the protrusion 45a in the protruding direction are: such dimensions that prevent entering of incident light entering the side surface of the transparent member 45 at a maximum expected angle; and such a distance and a length that do not interfere outermost incident light entering the outermost periphery of the light-receiving unit 44 at a maximum angle from the upper surface of the transparent member 45.

For example, when assuming that: the distance between the upper surface and the lower surface of the protrusion 45a is Y; the length of the lower surface of the protrusion 45a in the protruding direction is X; the maximum angle of outer incident light in the air is θ1; the maximum angle of the outer incident light in the transparent member 45 is θ2; the refractive index in the air is n1; and the refractive index of the transparent member 45 is n2, it is possible to determine X and Y using relational expressions of θ2=SIN⁻¹((n1·sinθ1)/n2) and X=TAN θ2·Y.

Thus, even when there is an error in the height of the sealing resin 47 formed for covering the end surfaces 54a and 54b of the transparent member 45, the sealing resin 47 can be formed such that it does not overtop the upper surface of the transparent member 45, but covers the entire end surface 54b below the step 46. Even when the sealing resin 47 cannot cover the upper end of the end surface 54a of the transparent member 45, it is possible to prevent entering of undesired incident light from the end surface 54a of the protrusion 45a, as a result of the sealing resin 47 that shields light and covers the end surface 54b below the step 46. For this reason, the miniaturization and cost reduction of the optical device 41 are possible.

### <Method for Manufacturing Optical Device>

Next is a description of a method for manufacturing the optical device 41 according to Embodiment 4.

Initially prepared is the optical element 43 which has: the light-receiving unit 44 at the surface center; and the electrodes 48 at the periphery that are electrically connected to the light-receiving unit 44. Subsequently, the resin adhesive 53 made of an acrylic resin, an epoxy resin, or a silicon resin, for example, is applied to the optical element 43 to cover the light-receiving unit 44. Then, the transparent member 45 is adhered to the resin adhesive 53 to cover the light-receiving unit 44.

Next, the housing 42 having a recess and made of an epoxy resin or alumina ceramics, for example, is prepared as a semiconductor package. The housing 42 includes leads 51 each of which has internal and external terminals. Subsequently, the optical element 43 is deposited on the recess of the housing 42 by using, for example, the thermosetting die bonding material 52 made of an epoxy resin or the like.

Next, each one of the internal electrodes 50 of the leads 51 of the housing 42 is electrically connected with a corresponding electrode 48 of the optical element 43 using a corresponding thin metal wire 49 made of Al or Au, for example. Then, using a draw-coating technique or a print-coating technique, for example, the space between the optical element 43 and the transparent member 45 in the recess of the housing 42 is filled with the sealing resin 47. As the sealing resin 47, a sealing resin primarily made of an epoxy resin, a urethane resin, a silicon resin, or the like may be used. Alternatively, an adhesive primarily made of such materials may be used.

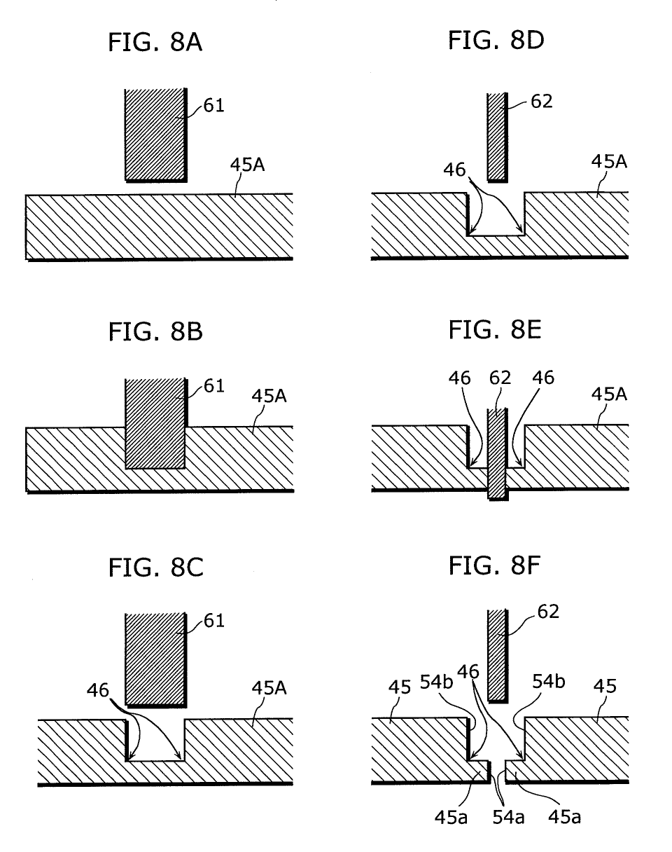

The most part of the above method for manufacturing the optical devices 1 and 41 according to Embodiments 1 to 4 can be implemented using a known method, and is not limited to the above-described method. However, a method for manufacturing the transparent member 45, which is a characteristic part of the method for manufacturing the optical device 41 according to Embodiment 4, is hereinafter described in detail with reference to FIGS. 8A to 8F.

Initially, as shown in FIG. 8A, a base material 45A for forming the transparent member 45 and a half-cutting blade 61 are made ready for use. Then, as shown in FIGS. 8B and 8C, the base material 45A is cut partway using the half-cutting blade 61. As a result, a recess is created in the base material 45A. The side walls of the recess are equivalent to the end surfaces 54b below the steps 46. That is to say, the depth of the recess (in the vertical direction in FIG. 8C) is substantially the same as the height of the end surfaces 54b.

Next, as shown in FIG. 8D, a full-cutting blade 62 having a bottom width (cut width) narrower than that of the half-cutting blade 61 is made ready for use. Subsequently, as shown in FIGS. 8E and 8F, the center of the portion where the steps 46 are formed is cut off. As a result, the protrusions 45a are formed. That is to say, the width of the recess in FIG. 8C (in the horizontal direction in FIG. 8C) is substantially equal to a sum of the protruding lengths of two protrusions 45a and the width of the full-cutting blade 62.

In the above series of processes shown in FIGS. 8A and 8F, the base material 45A is cut partway using the half-cutting blade 61 having a desirable bottom width, and then the base material 45A is cut off using the full-cutting blade 62 having a desirable bottom width so that the aforementioned steps 46 are formed. That is to say, the base material 45A is cut so that a relationship is established later between the distance (Y) between the upper surface and the lower surface of each protrusion 45a and the length (X) of the lower surface of each protrusion 45a in the protruding direction. As a result, the transparent members 45 are formed, each of which has the protrusion 45a and the end surfaces 54a and 54b as the side surface.

FIGS. 9A to 9C show another method for manufacturing the transparent member 45 which is a characteristic part of the method for manufacturing the optical device 41 according to Embodiment 4.

As shown in FIGS. 9A to 9C, an integrally-structured blade 71 is used which has a portion having the bottom width of the half-cutting blade 61 mounted to the tip of a portion having the bottom width of the full-cutting blade 62. By using such an integrally-structured blade 71, the transparent members 45 having the aforementioned structure can be formed by a single cutting process, that is, without two cutting processes of the half-cutting and the full-cutting shown in FIGS. 8A to 8F.

### Embodiment 5

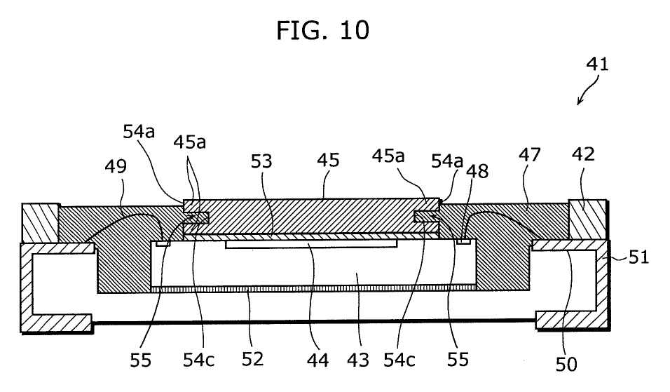

FIG. 10 is a sectional view of the optical device 41 according to Embodiment 5.

As shown in FIG. 10, the structure described in Embodiment 5 is the same as that shown in FIGS. 7A and 7B except in that the protrusions 45a are provided on the side surface of the transparent member 45 such that they face each other in the vertical direction, and in that such protrusions 45a facing each other create a slit-like recess (groove) 55.

The relationship between the distance Y from the upper surface to the lower surface of the upper protrusion 45a and the length X of the lower surface of the protrusion 45a in the protruding direction is the same as the aforementioned relationship. Therefore, by filling with the sealing resin 47 such that the end surface 54c of each recess is all covered, it is possible to obtain the above-described advantageous effect.

It is to be noted that as a method for forming the protrusions 45a having the recess 55, it is sufficient to perform the following operations, for example. In such a manner that the aforementioned protrusions 45a facing each other create the recess 55, first, the base material 45A is divided using the full-cutting blade 62 having a desired bottom width, and then, by an etching process using a mask, the portion equivalent to the recess 55 is removed from the divided base material 45A so that the transparent member 45 having the recess 55 can be formed from the divided base material 45A.

### Embodiment 6

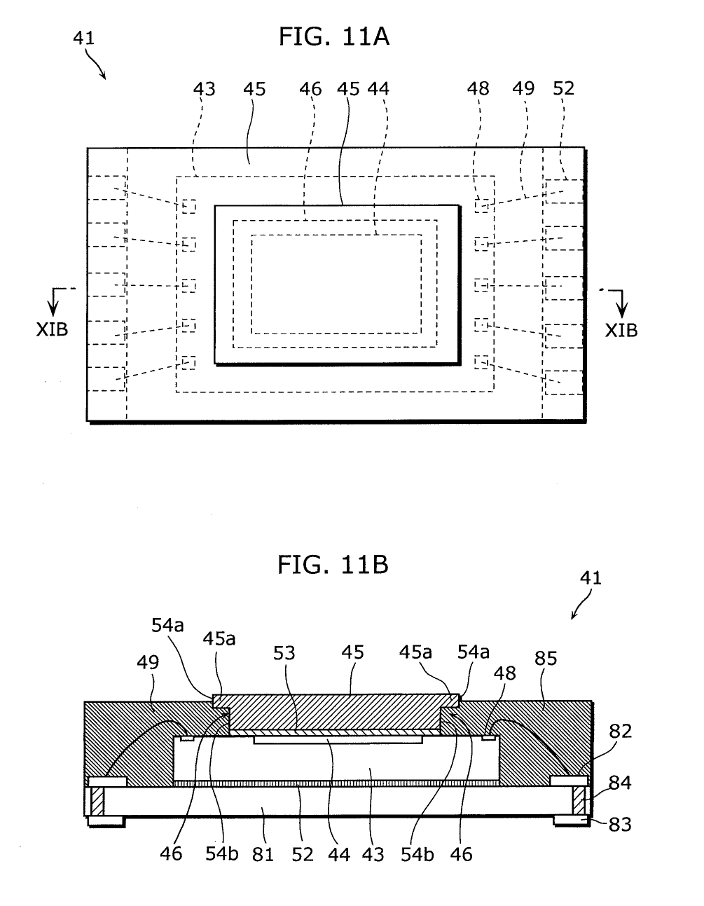

FIG. 11A is a plan view showing the structure of the optical device 41 according to Embodiment 6. FIG. 11B is a cross-sectional view taken along the XIB-XIB line of FIG. 11A.

As shown in FIGS. 11A and 11B, the structure of Embodiment 6 is basically the same as that shown in FIGS. 7A and 7B except: that the optical element 43 and the transparent member 45 are packaged using a circuit substrate 81 (equivalent to the “circuit substrate 21” of Embodiment 3); and in some structural differences attributable to such a packaged structure.

The circuit substrate 81 has a circuit thereon, and is formed with a resin or ceramics as the base material, for example. Internal electrodes 82 (equivalent to the “internal electrodes 22” of Embodiment 3) are formed on one side of the circuit substrate 81, and external electrodes 83 (equivalent to the “external electrode 23” of Embodiment 3) are formed on the other side of the circuit substrate 81. The circuit substrate 81 is also formed with vias 84 (equivalent to the “vias 24” of Embodiment 3) which allow electrical conduction of the internal electrodes 82 and the external electrodes 83. It is to be noted that the vias may be inner-layer wires or the like instead.

The optical element 43 having the light-receiving unit 44 at the surface center is deposited on the circuit substrate 81 via the die bonding material 52. The transparent member 45 having the protrusions 45a, the structure and material of which are described in detail with reference to FIGS. 7A and 7B, is adhered on the optical element 43 via the resin adhesive 53 such that the light-receiving unit 44 is covered. Each of the electrodes 48 formed at the surface edges of the optical element 43 is electrically connected to a corresponding internal electrode 82 of the circuit substrate 81 via a corresponding thin metal wire 49.

The optical element 43 and the transparent member 45 are sealed by a sealing resin 85 which shields light (equivalent to the “sealant 25” of Embodiment 3). It is to be noted that the material and so on of each constituent component shown in FIGS. 11A and 11B is the same as that described with reference to FIGS. 7A and 7B. In Embodiment 6, a lead frame may be used in place of the circuit substrate 81 for packaging in the same manner.

With the structure according to Embodiment 6, a region equivalent to the side wall of the housing 42 shown in FIGS. 7A and 7B is not needed, allowing further miniaturization of the optical device 41. Further, since the circuit substrate 81 or the lead frame is used for the packaging, various and general-purpose packaging is possible, leading to cost reduction.

The method for manufacturing the optical device according to Embodiment 6 is basically the same as the above-described manufacturing methods with respect to the portions common to the structure of the optical device of FIGS. 7A and 7B. With the structure of Embodiment 6 in which the circuit substrate 81 is used instead of the housing 42, the constituent component for sealing the optical element 43 and the transparent member 45 on the circuit substrate 81 is formed by potting, printing, or molding with an acrylic resin, an epoxy resin, a silicon resin, or the like.

The optical device 1 according to Embodiment 1 can be provided by combining Embodiments 2 and 4. Combining Embodiments 2 and 4 allows further miniaturization of the optical device 1 as a result of a synergy effect of the protrusion 12b and the tapered surface 13. Further, with the optical device 1 according to Embodiment 1, it is possible to achieve one or both of: the effect of reducing the taper angle θc of the tapered surface 13 as compared to Embodiment 2; and the effect of reducing the protruding amount of the protrusion 12b as compared to Embodiment 4.

The optical device according to the present invention is not limited to the combination of Embodiments 2 and 4, but can be realized also by combining any one of Embodiments 2 and 3 and any one of Embodiments 4 to 6.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The optical device according to the present invention can prevent entering of undesired incident light and achieve miniaturization and cost reduction. Thus, the optical device according to the present invention is useful particularly for small electronic appliances.

What is claimed is:

1. An optical device comprising:
an optical element including a light-receiving unit;
a transparent member deposited on said optical element to cover said light-receiving unit; and
a sealant formed to seal around said transparent member,
wherein said transparent member includes:
a first protrusion formed in an upper region of a side surface of said transparent member such that a step is created on the side surface; and
a tapered surface on an end surface of said first protrusion, said tapered surface being sloped such that a cross-sectional area of said transparent member decreases towards an upper side of said transparent member, and
said sealant covers entirely at least a part of the side surface of said transparent member, the part of the side surface being located below said first protrusion.

2. The optical device according to claim 1,
wherein said tapered surface has a horizontal length longer than a vertical length.

3. The optical device according to claim 1,
wherein an angle between an upper surface of said transparent member and said tapered surface is equal to or smaller than 45°.

4. The optical device according to claim 1,
wherein said tapered surface is rougher than a different surface of said transparent member on which said tapered surface is not provided.

5. The optical device according to claim 1,
wherein a ridge line of said transparent member except for said tapered surface is chamfered.

6. The optical device according to claim 1,
wherein said transparent member further includes a second protrusion in a lower region of the side surface, said second protrusion being formed to create, together with said first protrusion, a recess at the step.

7. The optical device according to claim 1,
wherein said sealant is made of a light-shielding material.

8. The optical device according to claim 1,
wherein a height of said sealant reaches a point between a lower surface and an upper surface of said first protrusion.

9. The optical device according to claim 1, further comprising
a case for storing said optical element and said transparent member,
wherein said sealant fills an inside of said case and seals a space defined by surfaces of said optical element, said transparent member, and said case, and
an upper surface of said sealant is higher than a lower end of said tapered surface but lower than an upper end of said tapered surface.

10. A solid-state imaging device comprising:
a solid-state imaging element including a light-receiving unit;
a transparent member deposited on said solid-state imaging element to cover said light-receiving unit; and
a sealant formed to seal around said transparent member,
wherein said transparent member includes:
a first protrusion formed in an upper region of a side surface of said transparent member such that a step is created on the side surface; and
a tapered surface on an end surface of said first protrusion, said tapered surface being sloped such that a cross-sectional area of said transparent member decreases towards an upper side of said transparent member, and
said sealant covers entirely at least a part of the side surface of said transparent member, the part of the side surface being located below said first protrusion.

11. A method for forming the first protrusion and the tapered surface on the transparent member according to claim 1, said method comprising:
forming a recess to create the step on a lower surface of a substrate which is an original material of the transparent member;
forming a V-shaped groove on an upper surface of the substrate directly above the recess, using a V-shaped cutting tool having an angle of contact equal to an angle between the upper surface of the transparent member and the tapered surface; and
cutting the substrate using a deepest part of the V-shaped groove as a base point.

12. The method according to claim 11,
wherein said forming a V-shaped groove and said cutting the substrate are performed simultaneously, using a combined cutting tool that includes: a V-shaped first cutting tool having an angle of contact equal to the angle between the upper surface of the transparent member and the tapered surface; and a second cutting tool which is mounted to a tip of the first cutting tool and cuts the substrate in a direction perpendicular to the, upper surface of the substrate, the substrate being the original material of the transparent member.
